(19) United States
(12) Patent Application Publication
(10) Pub. No.: US 2025/0266050 A1
(43) Pub. Date: Aug. 21, 2025

(54) CREATION METHOD AND CREATION APPARATUS

(71) Applicant: FUJIFILM Corporation, Tokyo (JP)

(72) Inventors: Yukinori NISHIYAMA, Saitama-shi (JP); Kazuya OKIYAMA, Saitama-shi (JP); Mototada OTSURU, Saitama-shi (JP)

(73) Assignee: FUJIFILM Corporation, Tokyo (JP)

(21) Appl. No.: 19/203,156

(22) Filed: May 8, 2025

Related U.S. Application Data
(63) Continuation of application No. PCT/JP2023/037767, filed on Oct. 18, 2023.

(30) Foreign Application Priority Data
Nov. 22, 2022 (JP) 2022-186836

(51) Int. Cl. G10L 19/018; H03M 7/30

(52) U.S. Cl. CPC G10L 19/018; H03M 7/3059

(57) ABSTRACT

A creation method of the present disclosure includes an acquisition step of acquiring first sound data of a floating point format, based on a sound that is generated from a sound source and is collected by a sound collection device, and an accessory information creation step of creating accessory information that is attached to the first sound data and includes device information, which relates to the sound collection device, or sound source information, which relates to the sound source.

### CROSS-REFERENCE TO RELATED APPLICATIONS

This application is a continuation application of International Application No. PCT/JP2023/037767, filed Oct. 18, 2023, the disclosure of which is incorporated herein by reference in its entirety. Further, this application claims priority from Japanese Patent Application No. 2022-186836, filed on Nov. 22, 2022, the disclosure of which is incorporated herein by reference in its entirety.

### BACKGROUND

### 1. Technical Field

The technique of the present disclosure relates to a creation method and a creation apparatus.

### 2. Description of the Related Art

JP2012-073435A discloses an audio signal conversion device that samples an input analog audio signal of an L channel and an R channel with a sampling frequency of 192 kHz and a quantization bit rate of 24 bits in an A/D conversion device to generate a digital signal. A signal processing device is connected to an output side of the A/D conversion device. This signal processing device performs processing of down-sampling the frequency to ¼ (48 kHz) and processing of converting the down-sampled signal into a floating point format of a quantization bit rate of 32 bits.

JP2002-246913A discloses a data processing device that converts input data from a fixed point format to a floating point format by a conversion unit.

### SUMMARY

An object of one embodiment according to the technique of the present disclosure is to provide a creation method and a creation apparatus capable of improving quality of sound data.

In order to achieve the above object, a creation method of the present disclosure comprises an acquisition step of acquiring first sound data of a floating point format, based on a sound that is generated from a sound source and is collected by a sound collection device, and an accessory information creation step of creating accessory information that is attached to the first sound data and includes device information, which relates to the sound collection device, or sound source information, which relates to the sound source.

It is preferable that the first sound data is used to create second sound data having the number of bits, which is smaller than the number of bits of the first sound data.

It is preferable that the accessory information includes the device information. In this case, it is preferable that the device information relates to gain processing used for the sound collected by the sound collection device or relates to performance of the sound collection device.

It is preferable that the accessory information includes the sound source information. In this case, it is preferable that the sound source information is associated with time information included in the first sound data.

It is preferable that the creation method further comprises an imaging step of creating, by an imaging apparatus, video data corresponding to the first sound data.

It is preferable that the sound source is a subject included in the video data.

It is preferable that the sound source is a main subject selected from a plurality of subjects included in the video data.

It is preferable that the sound source information is a type of a drive sound accompanied by drive of the imaging apparatus.

It is preferable that the creation method further comprises a first file creation step of creating a first file including the first sound data and the accessory information.

It is preferable that the creation method further comprises an editing step of editing the first sound data based on the accessory information to create second sound data having the number of bits, which is smaller than the number of bits of the first sound data.

In the editing step, deterioration information that relates to a sound of the second sound data deteriorated by the editing may be created, and a second file including the second sound data and the deterioration information may be created. It is preferable that the second file includes the accessory information.

A creation apparatus according to the present disclosure comprises a processor, in which the processor is configured to execute an acquisition step of acquiring first sound data of a floating point format, based on a sound that is generated from a sound source and is collected by a sound collection device, and an accessory information creation step of creating accessory information that is attached to the first sound data and includes device information, which relates to the sound collection device, or sound source information, which relates to the sound source.

### BRIEF DESCRIPTION OF THE DRAWINGS

Exemplary embodiments according to the technique of the present disclosure will be described in detail based on the following figures, wherein:

FIG. 1 is a diagram showing an example of a configuration of an imaging apparatus according to a first embodiment,

FIG. 2 is a diagram showing an example of a configuration of a sound signal processing circuit,

FIG. 3 is a diagram conceptually showing sound signal processing,

FIG. 4 is a diagram showing an example of a functional configuration of a processor,

FIG. 5 is a diagram conceptually showing combination processing and data format conversion processing,

FIG. 6 is a diagram conceptually showing editing processing,

FIG. 7 is a flowchart showing an example of an operation of the imaging apparatus,

FIG. 8 is a diagram showing an example of a functional configuration of the processor according to a second embodiment,

FIG. 9 is a diagram showing an example of a relationship between sound source information and first sound data,

FIG. 10 is a flowchart showing an example of an operation of the imaging apparatus according to the second embodiment,

FIG. 11 is a diagram showing an example of a functional configuration of the processor according to a third embodiment,

FIG. 12 is a diagram showing an example of the relationship between the sound source information and the first sound data according to the third embodiment, and

FIG. 13 is a diagram showing an example of a sound data file created by an editing unit.

### DETAILED DESCRIPTION

An example of an embodiment according to the technique of the present disclosure will be described with reference to accompanying drawings.

First, terms used in the following description will be described.

In the following description, “AF” is an abbreviation for “auto focus”. “MF” is an abbreviation for “manual focus”. “IC” is an abbreviation for “integrated circuit”. “CPU” is an abbreviation for “central processing unit”. “RAM” is an abbreviation for “random access memory”. “CMOS” is an abbreviation for “complementary metal oxide semiconductor”.

“FPGA” is an abbreviation for “field programmable gate array”. “PLD” is an abbreviation for “programmable logic device”. “ASIC” is an abbreviation for “application specific integrated circuit”. “OVF” is an abbreviation for “optical view finder”. “EVF” is an abbreviation for “electronic view finder”. “ADC” is an abbreviation for “analog to digital converter”. “LPCM” is an abbreviation for “linear pulse code modulation”.

As an embodiment of an imaging apparatus, the technique of the present disclosure will be described by using a lens-interchangeable digital camera as an example. The technique of the present disclosure is not limited to the lens-interchangeable type, and can be employed for a lens-integrated digital camera.

### First Embodiment

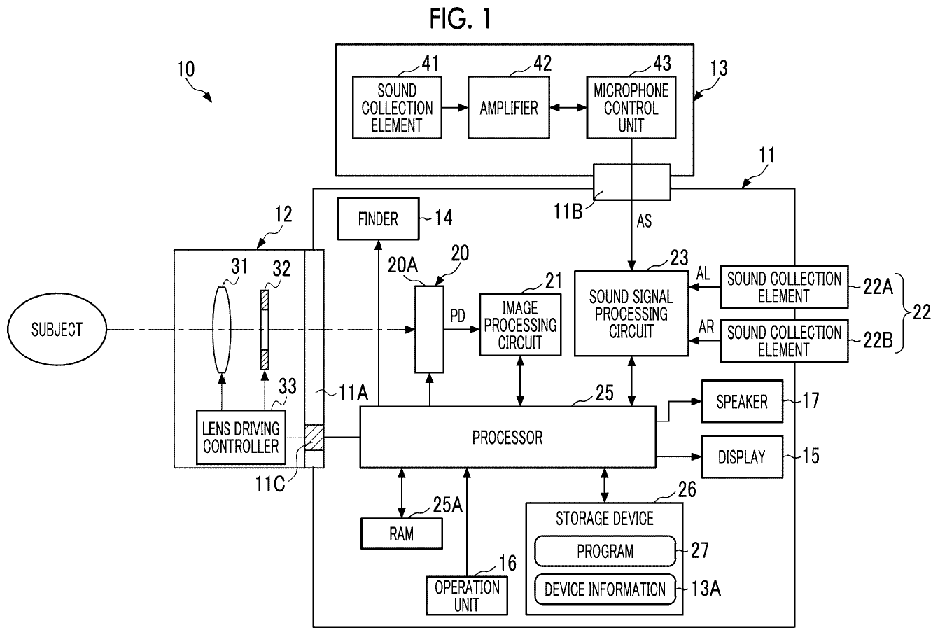

FIG. 1 shows an example of a configuration of an imaging apparatus 10 according to a first embodiment. The imaging apparatus 10 is the lens-interchangeable digital camera. The imaging apparatus 10 is configured of a housing 11 and an imaging lens 12 that is interchangeably mounted on the housing 11 and includes a focus lens 31. The imaging lens 12 is attached to a front surface side of the housing 11 via a mount 11A. The imaging apparatus 10 is an example of “creation apparatus” according to the technique of the present disclosure.

Further, an external microphone 13 can be attachably and detachably attached to the housing 11. The external microphone 13 is attached to the housing 11 via a connecting part 11B provided on an upper surface of the housing 11. The external microphone 13 is a gun microphone, a zoom microphone, or the like. The connecting part 11B is, for example, a hot shoe. The external microphone 13 is an example of “sound collection device” according to the technique of the present disclosure.

The housing 11 is provided with an operation unit 16 including a dial, a release button, and the like. Examples of an operation mode of the imaging apparatus 10 include a still image capturing mode, a video capturing mode, and an image display mode. The operation unit 16 is operated by a user in a case where the operation mode is set. Further, the operation unit 16 is operated by the user in a case where execution of still image capturing or video capturing is started.

Further, the operation unit 16 is operated by the user in a case where a focusing mode is selected. The focusing mode includes an AF mode and an MF mode. In the AF mode, a subject area selected by the user or a subject area automatically detected by the imaging apparatus 10 is set as a focus detection area (hereinafter referred to as AF area) to perform focusing control. In the MF mode, the user operates a focus ring (not shown) to manually perform the focusing control.

Further, the housing 11 is provided with a finder 14. For example, the finder 14 is a hybrid finder (registered trademark). The hybrid finder refers to, for example, a finder in which an optical view finder (hereinafter referred to as “OVF”) and an electronic view finder (hereinafter referred to as “EVF”) are selectively used. The user can observe an optical image or live view image of a subject projected onto the finder 14 via a finder eyepiece portion (not shown).

Further, a display 15 is provided on a rear surface side of the housing 11. The display 15 displays an image based on video data PD obtained by imaging, various menu screens, and the like. The user can also observe the live view image projected onto the display 15, instead of the finder 14.

Further, the housing 11 is provided with a speaker 17. The speaker 17 outputs a sound based on second sound data AS2 included in a moving image file 28 described below.

The housing 11 is electrically connected to the imaging lens 12 via an electrical contact 11C provided on the mount 11A.

The imaging lens 12 includes a focus lens 31, a stop 32, and a lens driving controller 33. The lens driving controller 33 is electrically connected to a processor 25 accommodated in the housing 11, via the electrical contact 11C.

The lens driving controller 33 drives the focus lens 31 and the stop 32, based on control signals transmitted from the processor 25. The lens driving controller 33 performs drive control of the focus lens 31, based on the control signal for the focusing control that is transmitted from the processor 25, in order to adjust a position of the focus lens 31.

The stop 32 has an opening with a variable opening diameter. The lens driving controller 33 performs drive control of the stop 32, based on the control signal for stop adjustment that is transmitted from the processor 25, in order to adjust an amount of light incident on an imaging sensor 20.

Further, the imaging sensor 20, an image processing circuit 21, a built-in microphone 22, a sound signal processing circuit 23, the processor 25, and a storage device 26 are provided inside the housing 11. The processor 25 controls operations of the imaging sensor 20, the image processing circuit 21, the built-in microphone 22, the sound signal processing circuit 23, the storage device 26, the display 15, and the speaker 17.

The processor 25 is configured of, for example, a CPU. The processor 25 is connected to a RAM 25A, which is a memory for primary storage. The storage device 26 is configured of, for example, a non-volatile memory such as a flash memory. The processor 25 executes various types of processing based on a program 27 stored in the storage device 26. The processor 25 may be configured of an assembly of a plurality of IC chips.

The imaging sensor 20 is, for example, a CMOS-type image sensor. Light (subject image) that has passed through the imaging lens 12 is incident on a light-receiving surface 20A of the imaging sensor 20. A plurality of pixels that generate imaging signals through photoelectric conversion are formed on the light-receiving surface 20A. The imaging sensor 20 performs the photoelectric conversion on light incident on each pixel to generate and output the video data PD.

The image processing circuit 21 performs, on the video data PD output from the imaging sensor 20, image processing including white balance correction, gamma correction processing, and the like.

The built-in microphone 22 is a stereo microphone including a pair of sound collection elements 22A and 22B. The sound collection elements 22A and 22B are sound sensors for a left side channel (hereinafter referred to as L channel) and a right side channel (hereinafter referred to as R channel). The sound collection elements 22A and 22B are sound sensors of an electrostatic type, a piezoelectric type, an electrodynamic type, or the like, and output collected sounds as sound signals AL and AR. The sound signal processing circuit 23 performs sound signal processing including gain processing, A/D conversion processing, and the like on the sound signals AL and AR output from the sound collection elements 22A and 22B.

The external microphone 13 includes a sound collection element 41, an amplifier 42, and a microphone control unit 43. In the present embodiment, the external microphone 13 is a mono microphone having one sound collection element 41. The sound collection element 41 is a sound sensor of an electrostatic type, a piezoelectric type, an electrodynamic type, or the like, and outputs a collected sound as the sound signal. The amplifier 42 performs the gain processing on the sound signal output from the sound collection element 41. The microphone control unit 43 controls a gain amount of the gain processing by the amplifier 42.

Further, the microphone control unit 43 supplies the sound signal subjected to the gain processing by the amplifier 42 to the sound signal processing circuit 23 in the housing 11 via the connecting part 11B. A mono and analog sound signal AS is supplied from the external microphone 13 to the sound signal processing circuit 23. The processor 25 controls the operation of the microphone control unit 43.

Further, the storage device 26 stores device information 13A, which is information related to the external microphone 13. In the present embodiment, information related to the gain processing used for the collected sound using the device information 13A is employed. Specifically, the device information 13A is the gain amount (that is, sensitivity of the external microphone 13) of the gain processing by the amplifier 42.

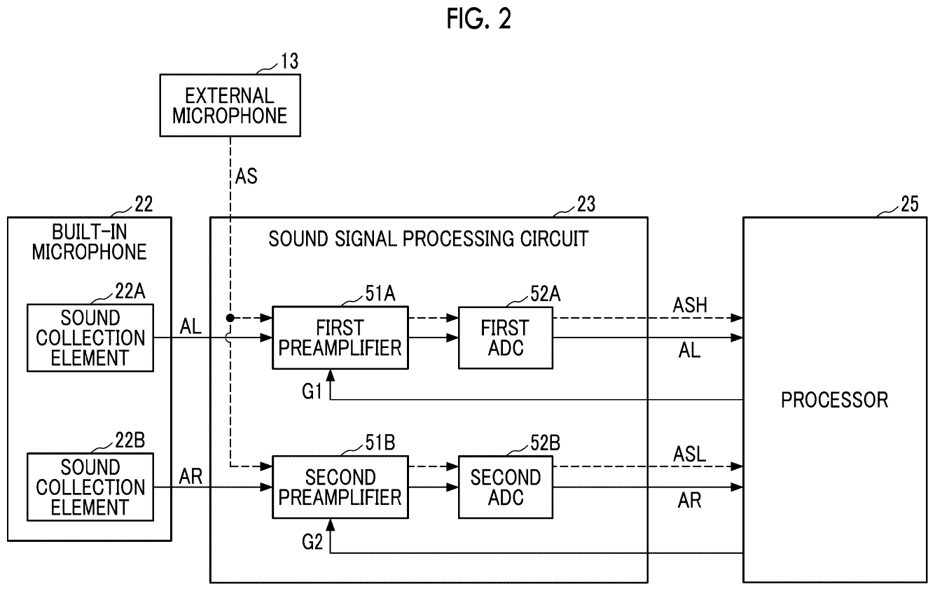

FIG. 2 shows an example of a configuration of the sound signal processing circuit 23. The sound signal processing circuit 23 includes a first preamplifier 51A, a first ADC 52A, a second preamplifier 51B, and a second ADC 52B.

The first preamplifier 51A and the first ADC 52A are processing units for L-channel that perform the gain processing and the A/D conversion processing on the sound signal AL output from the sound collection element 22A included in the built-in microphone 22. The second preamplifier 51B and the second ADC 52B are processing units for R-channel that perform the gain processing and the A/D conversion processing on the sound signal AR output from the sound collection element 22B included in the built-in microphone 22.

In the first preamplifier 51A, the processor 25 controls a gain amount G1. In the second preamplifier 51B, the processor 25 controls a gain amount G2. In a case where the gain processing is performed on the sound signals AL and AR output from the built-in microphone 22, the processor 25 sets the gain amount G1 and the gain amount G2 to the same value. The first ADC 52A and the second ADC 52B perform sampling with, for example, a quantization bit rate of 24 bits to convert an analog sound signal into a digital signal of a 24-bit LPCM format. The LPCM format is an example of “pulse code modulation format” according to the technique of the present disclosure.

The sound signal AS output from the external microphone 13 is input to the first preamplifier 51A and the second preamplifier 51B. The first preamplifier 51A performs the gain processing on the sound signal AS with the gain amount G1. The second preamplifier 51B performs the gain processing on the sound signal AS with the gain amount G2. In a case where the gain processing is performed on the sound signal AS output from the external microphone 13, the processor 25 sets the gain amount G1 and the gain amount G2 to different values. Hereinafter, the gain processing performed by the first preamplifier 51A is referred to as first gain processing, and the gain processing performed by the second preamplifier 51B is referred to as second gain processing.

The first ADC 52A converts the sound signal AS subjected to the first gain processing by the first preamplifier 51A into the digital signal. The second ADC 52B converts the sound signal AS subjected to the second gain processing by the second preamplifier 51B into the digital signal. Hereinafter, the sound signal AS digitized by the first ADC 52A is referred to as modulation sound data ASH, and the sound signal AS digitized by the second ADC 52B is referred to as modulation sound data ASL. The modulation sound data ASH and ASL are output from the sound signal processing circuit 23 to the processor 25.

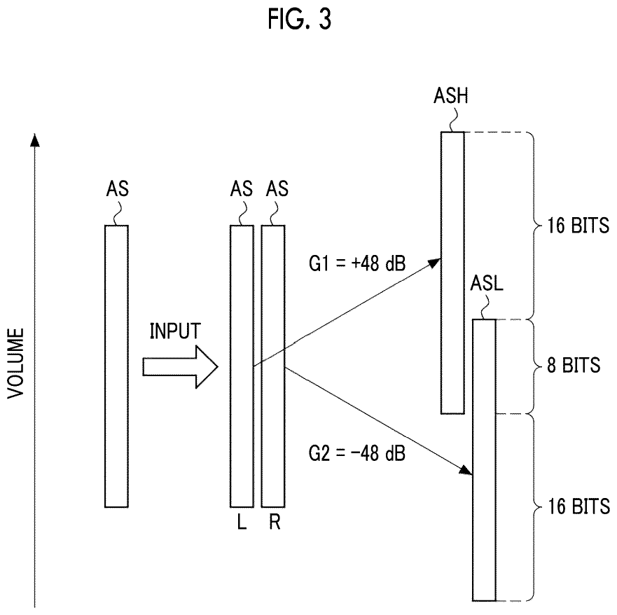

FIG. 3 conceptually shows sound signal processing of the sound signal AS by the sound signal processing circuit 23. The sound signal AS output from the external microphone 13 is input to the processing unit for L-channel and the processing unit for R-channel. The sound signal AS input to the processing unit for L-channel is subjected to the first gain processing with the gain amount G1, then is converted into the digital signal, and thus, is output from the sound signal processing circuit 23 as the modulation sound data ASH. The sound signal AS input to the processing unit for R-channel is subjected to the second gain processing with the gain amount G2, then is converted into the digital signal, and thus, is output from the sound signal processing circuit 23 as the modulation sound data ASL. In the present embodiment, the number of bits of the modulation sound data ASH and ASL is 24 bits.

For example, the gain amount G1 is assumed to be +48 dB, and the gain amount G2 is assumed to be −48 dB. Since 48 dB corresponds to a volume width of 8 bits, there is a deviation of 16 bits between the modulation sound data ASH of high gain and the modulation sound data ASL of low gain, as shown in FIG. 3. In other words, the modulation sound data ASH overlaps with the modulation sound data ASL by 8 bits.

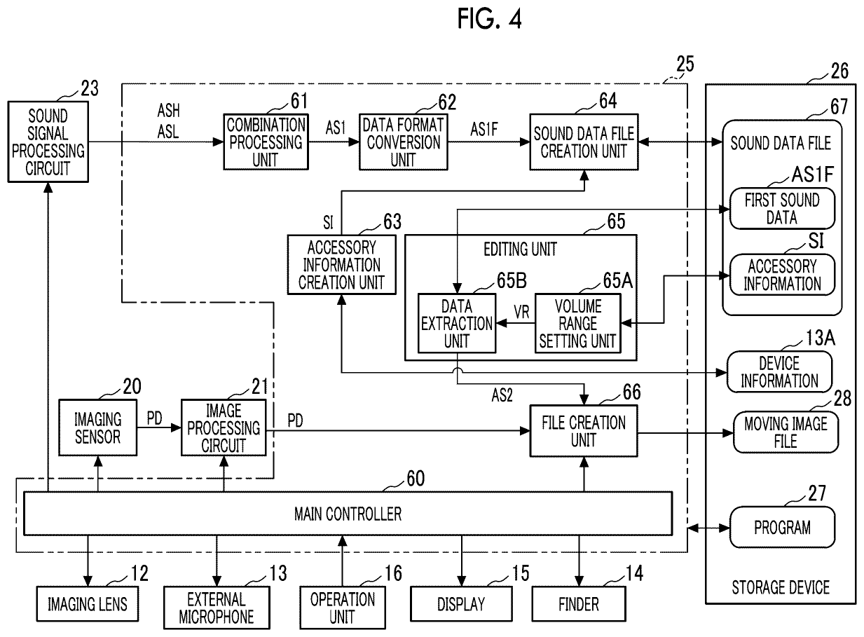

FIG. 4 shows an example of a functional configuration of the processor 25. The processor 25 executes the processing according to the program 27, which is stored in the storage device 26, to implement various functional units. Various functional units shown in FIG. 4 are implemented in the video capturing mode. As shown in FIG. 4, for example, a main controller 60, a combination processing unit 61, a data format conversion unit 62, an accessory information creation unit 63, a sound data file creation unit 64, an editing unit 65, and a file creation unit 66 are implemented in the processor 25. The editing unit 65 includes a volume range setting unit 65A and a data extraction unit 65B.

The main controller 60 integrally controls each unit of the imaging apparatus 10. The main controller 60 controls the operation of the imaging apparatus 10 based on an instruction signal input from the operation unit 16. The main controller 60 controls the imaging sensor 20 to cause the imaging sensor 20 to perform the imaging operation. The imaging sensor 20 outputs the video data PD, which is generated by performing the imaging via the imaging lens 12. In the video capturing mode, the imaging sensor 20 outputs the video data PD for each frame cycle. The video data PD output from the imaging sensor 20 is subjected to the image processing by the image processing circuit 21 and then input to the processor 25. In a case of the video capturing mode, the video data PD is data consisting of a plurality of frames.

Further, in the video capturing mode, in a case where the external microphone 13 is connected to the connecting part 11B, the main controller 60 controls the external microphone 13 to perform a sound collection operation. The external microphone 13 outputs the sound signal AS to the sound signal processing circuit 23 via the connecting part 11B while the imaging sensor 20 performs the imaging operation. The sound signal processing circuit 23 performs the above sound signal processing to output the modulation sound data ASH and ASL. The modulation sound data ASH and ASL correspond to the video data PD obtained by the imaging sensor 20 imaging the subject.

The combination processing unit 61 acquires the modulation sound data ASH and ASL output from the sound signal processing circuit 23, and combines the modulation sound data ASH and ASL to create first sound data AS1 having a first number of bits. The first sound data AS1 is digital data of the LPCM format.

The data format conversion unit 62 converts a data format of the first sound data AS1 into a floating point format. Hereinafter, the first sound data AS1 converted into the floating point format is referred to as first sound data AS1F. The first sound data AS1F is used to create the second sound data AS2 having the number of bits smaller than the number of bits of the first sound data AS1F.

The accessory information creation unit 63 reads out the device information 13A from the storage device 26 to create accessory information SI including the device information 13A. The accessory information creation unit 63 supplies the created accessory information SI to the sound data file creation unit 64. The accessory information SI is so-called meta information.

The sound data file creation unit 64 creates a sound data file 67 including the first sound data AS1F, which is created by the data format conversion unit 62, and the accessory information SI, which is created by the accessory information creation unit 63. The sound data file creation unit 64 records the created sound data file 67 in the storage device 26. The sound data file 67 corresponds to “first file” according to the technique of the present disclosure.

The editing unit 65 edits the first sound data AS1F included in the sound data file 67, which is recorded in the storage device 26, based on the accessory information SI to create the second sound data AS2 having a second number of bits smaller than the first number of bits. For example, the second number of bits is 24 bits.

Specifically, the volume range setting unit 65A sets a volume range VR having a width of the second number of bits for a dynamic range of the first sound data AS1F. In the present embodiment, the volume range setting unit 65A sets the volume range VR based on the accessory information SI. The data extraction unit 65B extracts data of the volume range VR set by the volume range setting unit 65A to create the second sound data AS2, based on the first sound data AS1F.

The file creation unit 66 creates the moving image file 28 including the video data PD, which is output from the image processing circuit 21, and the second sound data AS2, which is output from the data extraction unit 65B, and stores the moving image file 28 in the storage device 26.

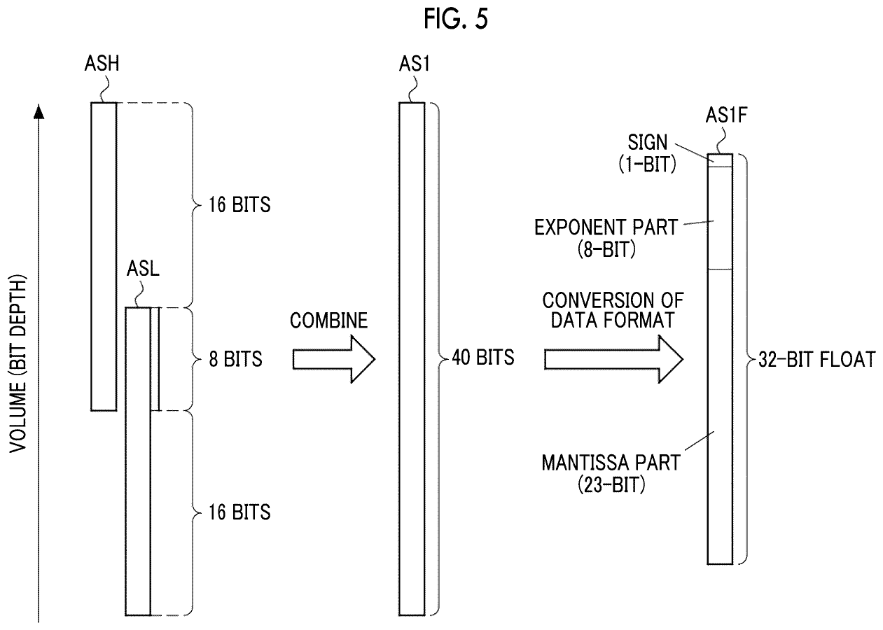

FIG. 5 conceptually shows combination processing by the combination processing unit 61 and data format conversion processing by the data format conversion unit 62. The combination processing unit 61 performs the mixing process on the overlap portion of 8 bits between the modulation sound data ASH and ASL to combine the modulation sound data ASH and the modulation sound data ASL. The number of bits (that is, the first number of bits) of the first sound data AS1, which is generated by the combination processing, is 40 bits. In this manner, with the combination of the modulation sound data ASH and ASL having different gain amounts, it is possible to obtain the first sound data AS1 with an expanded volume dynamic range.

The data format conversion unit 62 converts the first sound data AS1 of a 40-bit fixed point format into the first sound data AS1F of a 32-bit floating point format (so-called 32-bit float). The 32-bit float is configured of a 1-bit sign, an 8-bit exponent part, and a 23-bit mantissa part. A known method can be used for the conversion from the fixed point format to the floating point format. In the floating point format, a wide range of numerical values can be expressed.

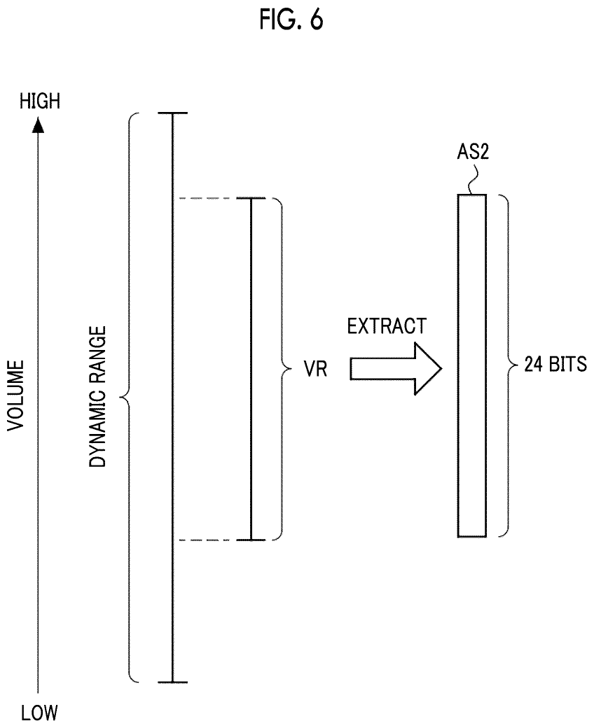

FIG. 6 conceptually shows editing processing by the editing unit 65. The volume range setting unit 65A sets the volume range VR based on the device information 13A included in the accessory information SI. Specifically, the volume range setting unit 65A sets the volume range VR based on the gain amount (that is, sensitivity of the external microphone 13) of the gain processing of the amplifier 42, which is an example of the device information 13A. For example, the volume range setting unit 65A sets the volume range VR to a low volume side as the gain amount is larger (that is, sensitivity is higher), and sets the volume range VR to a high volume side as the gain amount is smaller (that is, sensitivity is lower). Accordingly, it is possible to suppress sound cracking and the like.

The data extraction unit 65B extracts the data of the volume range VR to create the second sound data AS2, based on the first sound data AS1F. In this manner, with the creation of the second sound data AS2 based on the device information 13A, it is possible to generate the second sound data AS2 of the 24-bit fixed point format in which the sound cracking and the like are suppressed.

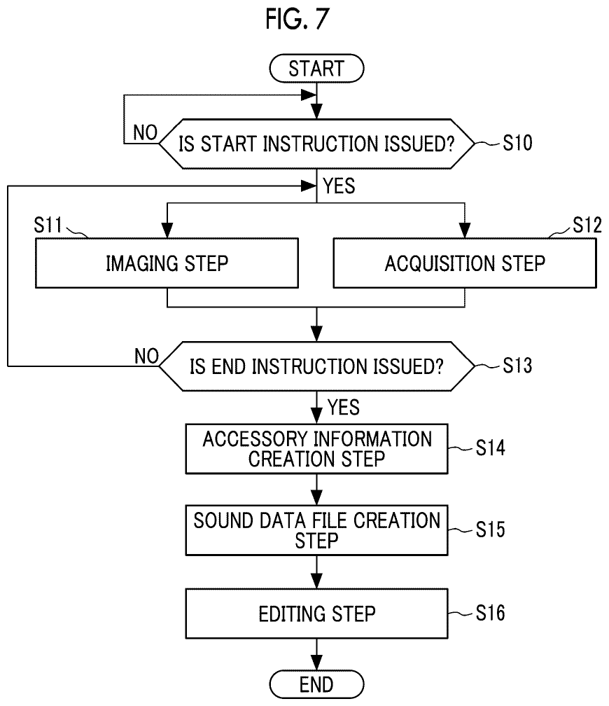

FIG. 7 is a flowchart showing an example of the operation of the imaging apparatus 10. FIG. 7 shows an operation in a case where the video capturing mode is selected as the operation mode and the external microphone 13 is connected to the connecting part 11B.

First, the main controller 60 determines whether or not the user issues a start instruction for the video capturing (step S10). In a case where the start instruction is determined to be issued (YES in step S10), an imaging step (step S11) and an acquisition step (step S12) are executed in parallel. In the imaging step, the imaging sensor 20 images the subject to generate the video data PD. In the acquisition step, the first sound data AS1F of the floating point format is acquired based on the sound collected by the external microphone 13.

After the imaging step and the acquisition step, the main controller 60 determines whether or not the user issues an end instruction for the video capturing (step S13). In a case where the end instruction is determined to be not issued (NO in step S13), the processing returns to steps S11 and S12. Steps S11 to S12 are repeatedly executed until the end instruction is determined to be issued in step S13.

In a case where the end instruction is determined to be issued (YES in step S13), an accessory information creation step is executed (step S14). In the accessory information creation step, the accessory information creation unit 63 creates the accessory information SI including the device information 13A.

After the accessory information creation step, a sound data file creation step is executed (step S15). In the sound data file creation step, the sound data file creation unit 64 creates the sound data file 67 including the first sound data AS1F and the accessory information SI. The sound data file creation step corresponds to “first file creation step” according to the technique of the present disclosure.

After the sound data file creation step, an editing step is executed (step S16). In the editing step, the first sound data AS1F is edited based on the accessory information SI to create the second sound data AS2. Thereafter, the moving image file 28 including the video data PD and the second sound data AS2 is created and recorded in the storage device 26. The operation of the imaging apparatus 10 is ended as described above.

As described above, a creation method of the present disclosure includes the acquisition step of acquiring the first sound data of the floating point format, based on the sound that is generated from a sound source such as the subject and is collected by the sound collection device, and the creation step of creating the device information that is the accessory information attached to the first sound data and is information related to the sound collection device. Accordingly, it is possible to improve quality of the sound data.

In the above embodiment, the device information 13A is the information related to the

sound collection device, but the device information 13A may be information related to performance of the sound collection device. The information related to the performance of the sound collection device includes a noise level, a maximum sound pressure level, an output impedance, and the like. In this case, the volume range setting unit 65A sets the volume range VR based on the information related to the performance of the external microphone 13.

The noise level represents susceptibility of the external microphone 13 to noise. In a case where the performance of the sound collection device is the noise level, the volume range setting unit 65A limits an upper limit of the volume range VR according to the noise level, for example. This is because, in a case where the noise level is small and the volume range VR is set to the high volume side, the sound from the subject as the sound source is difficult to hear due to the noise.

The maximum sound pressure level represents a sound pressure level at maximum at which the external microphone 13 can perform the sound collection. In a case where the performance of the sound collection device is the maximum sound pressure level, the volume range setting unit 65A limits the upper limit of the volume range VR according to the maximum sound pressure level, for example. This is because distortion may occur in a sound exceeding the maximum sound pressure level.

The output impedance represents magnitude of an internal resistance of the external microphone 13. In a case where the performance of the sound collection device is the output impedance, the volume range setting unit 65A sets the volume range VR to the low volume side as the output impedance is smaller, for example. This is because a voltage drop is smaller as the output impedance is lower, and thus the sound signal AS output from the external microphone 13 is less deteriorated. Further, the volume range setting unit 65A may limit the upper limit of the volume range VR according to the output impedance. This is because the voltage drop is larger as the output impedance is higher, and thus the noise included in the sound signal AS may be large. For example, the upper limit of the volume range VR is set lower as the output impedance is higher.

Further, the information related to the performance of the sound collection device may be a polar pattern. The polar pattern represents sensitivity (that is, directivity) to a sound collection direction of the external microphone 13. The polar pattern includes single directivity, bidirectional directivity, and omnidirectional directivity. The volume range setting unit 65A sets the volume range VR according to a type of the polar pattern, for example. Further, with consideration of the video data PD in addition to the polar pattern, it is possible to set the volume range VR to an optimal range such that the sound generated from the sound source such as the subject is included.

Further, the information related to the performance of the sound collection device may be a frequency range. The frequency range is a range of frequency of a sound that can be collected and reproduced by the external microphone 13.

### Second Embodiment

Next, a second embodiment will be described. In the first embodiment, the accessory information creation unit 63 creates the accessory information SI including the device information 13A. In the second embodiment, the accessory information creation unit 63 creates the accessory information SI including sound source information, instead of the device information 13A. The sound source information relates to the sound source such as the subject.

The configuration of the imaging apparatus 10 according to the second embodiment other than the processor 25 is the same as that of the first embodiment. In the following, the same reference numerals are assigned to the same components as those in the first embodiment, and the description thereof will be omitted as appropriate.

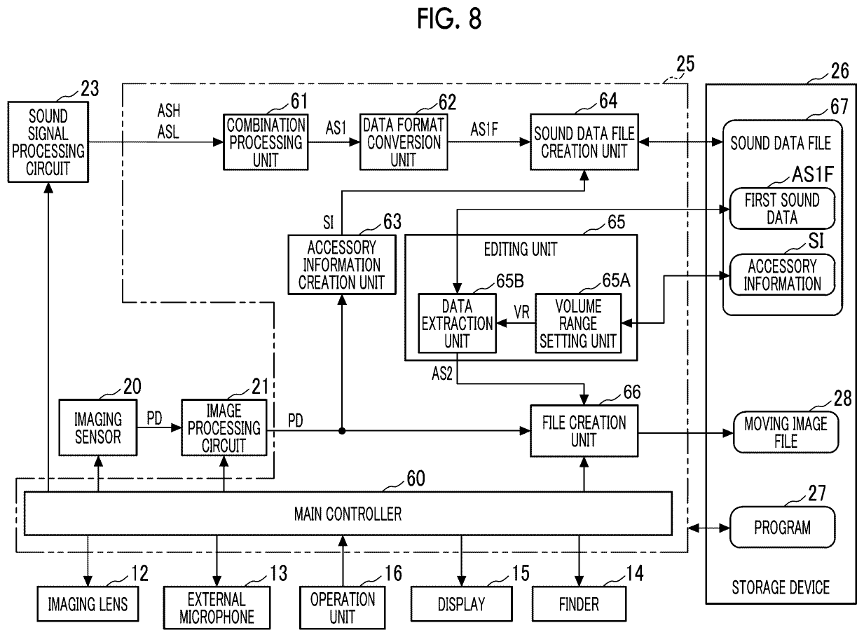

FIG. 8 shows an example of a functional configuration of the processor 25 according to the second embodiment. In the present embodiment, only the function of the accessory information creation unit 63 is different from that of the first embodiment. In the present embodiment, the accessory information creation unit 63 acquires the sound source information based on the video data PD output from the image processing circuit 21, and creates the accessory information SI including the acquired sound source information. In the present embodiment, the sound source is a main subject selected from a plurality of subjects, which are included in the video data PD. For example, the accessory information creation unit 63 acquires a type of the main subject as the sound source information, for each frame constituting the video data PD, during the imaging operation by the imaging apparatus 10.

The main subject is a subject determined to have high importance by the user or the main controller 60, among the plurality of subjects included in the video data PD. In the present embodiment, the volume range setting unit 65A sets the volume range VR based on the type of the main subject. For example, in a case where the type of the main subject is a type in which a generated sound is assumed to be high in volume, such as “airplane”, the volume range setting unit 65A sets the volume range VR to the high volume side. On the other hand, in a case where the type of the main subject is a type in which a generated sound is assumed to be low in volume, such as “person”, the volume range setting unit 65A sets the volume range VR to the low volume side.

Various types of processing can be employed as the processing in which the accessory information creation unit 63 selects the main subject from the plurality of subjects included in the video data PD. As an example, the accessory information creation unit 63 selects the main subject based on sizes of the plurality of subjects included in the video data PD. In this case, the accessory information creation unit 63 selects, as the main subject, a subject having a largest size among the plurality of subjects.

Further, the accessory information creation unit 63 can also select the main subject based on types of the plurality of subjects included in the video data PD. In this case, for example, the accessory information creation unit 63 determines the type of each subject and selects, as the main subject, a subject that matches a type set by the user using the operation unit 16. For example, in a case where a person imaging mode is set, the accessory information creation unit 63 selects a person as the main subject from the plurality of subjects included in the video data PD.

Further, the accessory information creation unit 63 can also select the main subject based on positions of the plurality of subjects included in the video data PD within an angle of view. In this case, for example, the accessory information creation unit 63 obtains the position of each subject within the angle of view to select, as the main subject, a subject located at a center of the angle of view.

Further, the accessory information creation unit 63 can also select the main subject based on a focusing position of the imaging lens 12. In this case, for example, the accessory information creation unit 63 acquires information related to the focusing position from the main controller 60 to select, as the main subject, a subject closest to the focusing position from the plurality of subjects included in the video data PD.

Further, the accessory information creation unit 63 can also select the main subject based on input information of the user. In this case, for example, the accessory information creation unit 63 selects, as the main subject, a subject located in the subject area selected by the user using the operation unit 16. The accessory information creation unit 63 may select, as the main subject, a subject located at the AF area automatically detected by the imaging apparatus 10.

Further, the accessory information creation unit 63 can also select the main subject based on visual line information of the user. In this case, for example, the imaging apparatus 10 has a function of detecting a visual line of the user who looks through the finder 14. The accessory information creation unit 63 acquires the visual line information of the user to select, as the main subject, a subject present at a position of the visual line within the angle of view.

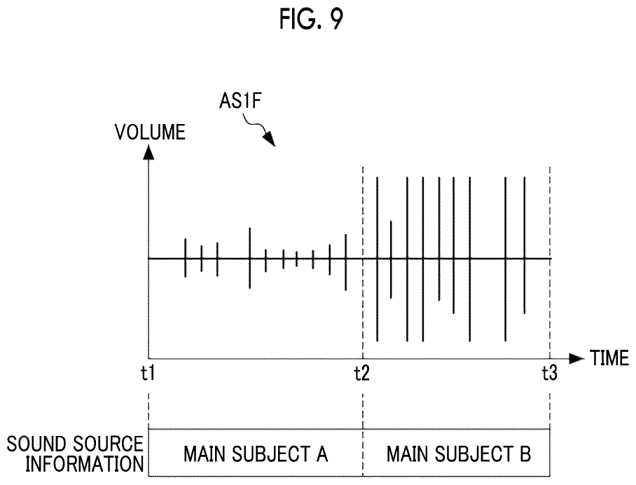

FIG. 9 shows an example of a relationship between the sound source information and the first sound data AS1F. As shown in FIG. 9, the first sound data AS1F represents a change in volume (that is, change in amplitude) to time. The sound source information is associated with time information included in the first sound data AS1F. In the example shown in FIG. 9, a main subject A is associated as the sound source information from t1 to t2, and a main subject B is associated as the sound source information from t2 to t3. The main subject A and the main subject B are of different types. For example, the main subject A is “person” of which a generated sound is low in volume, and the main subject B is “airplane” of which a generated sound is high in volume.

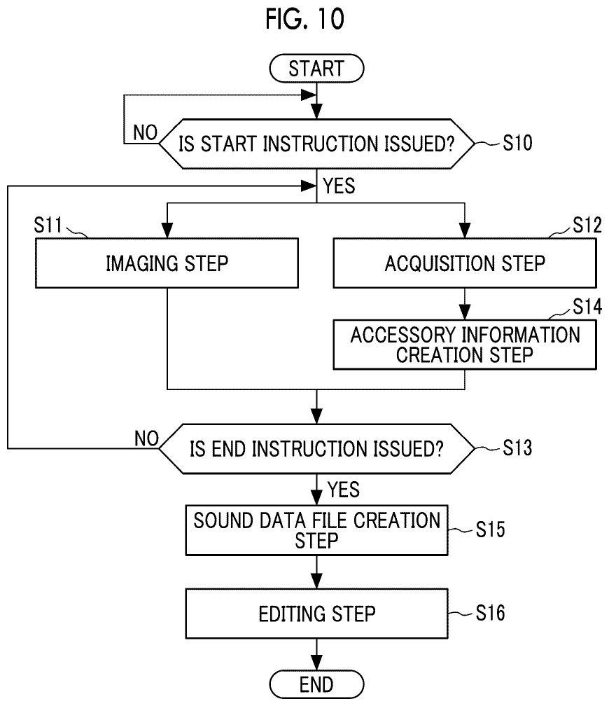

FIG. 10 is a flowchart showing an example of the operation of the imaging apparatus 10 according to the second embodiment. FIG. 10 shows an operation in a case where the video capturing mode is selected as the operation mode and the external microphone 13 is connected to the connecting part 11B.

The operation of the imaging apparatus 10 according to the present embodiment is different from the above embodiment only in the timing at which the accessory information creation step (step S14) is executed. In the present embodiment, since the sound source information changes over time, the accessory information creation step is executed after the acquisition step. That is, in the present embodiment, steps S11, S12, and S14 are repeatedly executed until the end instruction is determined to be issued in step S13. In a case where the end instruction is determined to be issued (YES in step S13), the sound data file creation step (step S15) and the editing step (step S16) are executed.

### Third Embodiment

Next, a third embodiment will be described. In the second embodiment, the sound source of the sound source information, which is acquired by the accessory information creation unit 63, is the subject. In the third embodiment, the sound source information acquired by the accessory information creation unit 63 is a type of a drive sound accompanied by drive of the imaging apparatus 10. For example, the type of the drive sound is a drive sound of the focus lens 31, a drive sound of the stop 32, and the like. In a case where the imaging apparatus 10 comprises a heat radiation fan, the type of the drive sound includes a drive sound of the heat radiation fan.

The configuration of the imaging apparatus 10 according to the third embodiment other than the processor 25 is the same as that of the first embodiment. In the following, the same reference numerals are assigned to the same components as those in the first embodiment, and the description thereof will be omitted as appropriate.

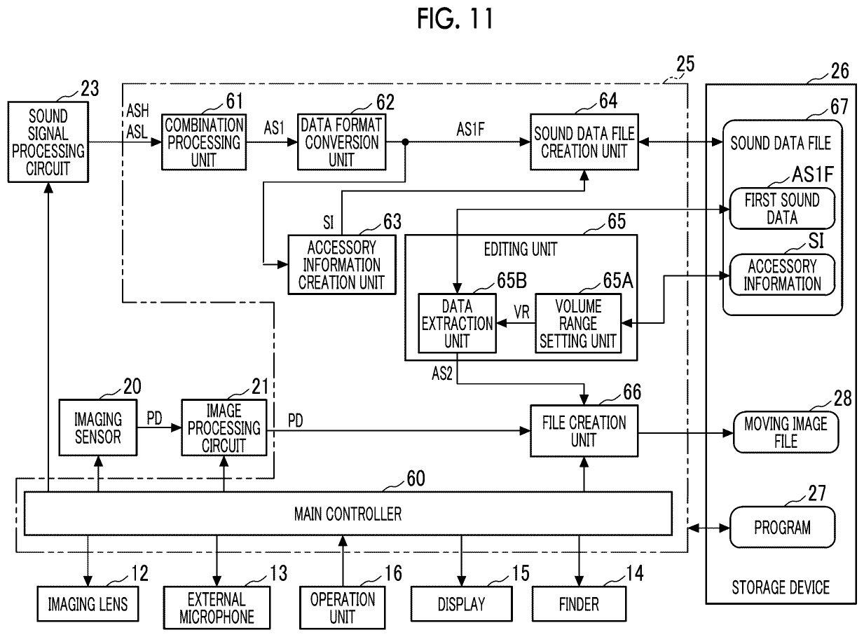

FIG. 11 shows an example of a functional configuration of the processor 25 according to the third embodiment. In the present embodiment, only the function of the accessory information creation unit 63 is different from that of the first embodiment. In the present embodiment, the accessory information creation unit 63 acquires the sound source information based on the first sound data AS1F output from the data format conversion unit 62 to create the accessory information SI including the acquired sound source information. The accessory information creation unit 63 acquires, as sound source information, the type of the drive sound accompanied by the drive of the imaging apparatus 10 during the imaging operation of the imaging apparatus 10. For example, the accessory information creation unit 63 analyzes the first sound data AS1F to determine the type of the drive sound.

The accessory information creation unit 63 is not limited to the first sound data AS1F, and may determine the type of the drive sound based on sound data such as the first sound data AS1 and the modulation sound data ASH and ASL. Further, the accessory information creation unit 63 may acquire, from the main controller 60, information representing a type of a device in operation to determine the type of the drive sound.

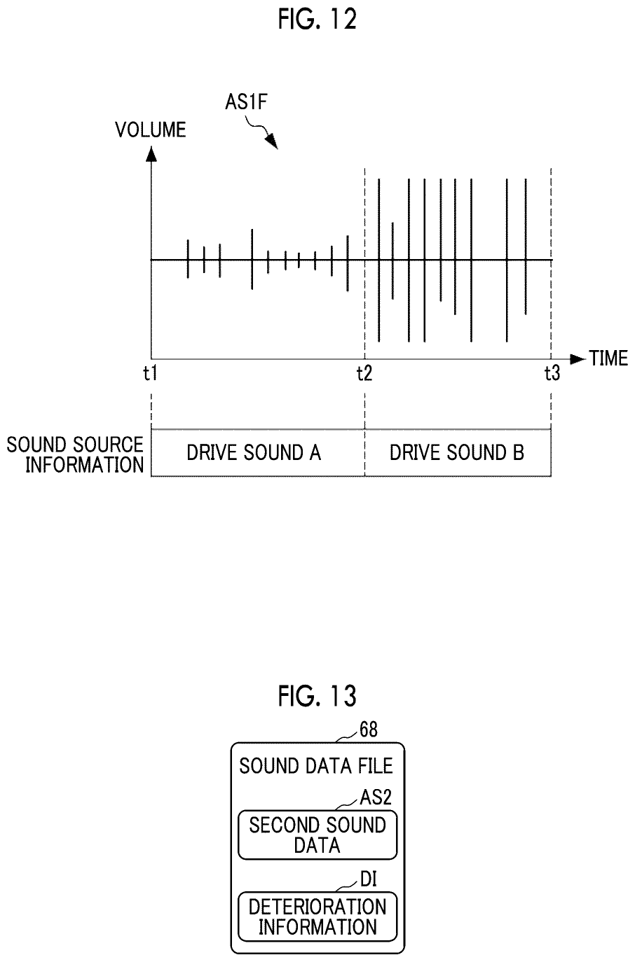

FIG. 12 shows an example of a relationship between the sound source information and the first sound data AS1F according to the third embodiment. The sound source information is associated with time information included in the first sound data AS1F. In the example shown in FIG. 9, a drive sound A is associated as the sound source information from t1 to t2, and a drive sound B is associated as the sound source information from t2 to t3. The drive sound A and the drive sound B are of different types. For example, the drive sound A is “drive sound of stop 32” in which a generated sound is low in volume, and the drive sound B is “drive sound of heat radiation fan” in which a generated sound is high in volume.

The operation of the imaging apparatus 10 according to the third embodiment is the same as that of the second embodiment except that the type of the drive sound is acquired as the sound source information in the accessory information creation step.

### Modification Example

Next, various modification examples will be described. In each of the above embodiments, the editing unit 65 edits the first sound data AS1F based on the accessory information SI to create the second sound data AS2. The editing unit 65 may create deterioration information DI, which relates to the sound of the second sound data AS2 deteriorated by the editing, and may create a sound data file 68 including the second sound data AS2 and the deterioration information DI as shown in FIG. 13. The editing unit 65 records the created sound data file 68 in the storage device 26. The sound data file 68 corresponds to “second file” according to the technique of the present disclosure.

The deterioration means that at least a part of the sound of the sound source included in the first sound data AS1F is not included in the volume range of the second sound data AS2. The deterioration information is sound information that is lost in a case where the second sound data AS2 having a smaller amount of information than the first sound data AS1F is created from the first sound data AS1F. The sound data file 68 may further include the accessory information SI.

The technique of the present disclosure is not limited to the digital camera and can also be employed for electronic devices such as a smartphone and a tablet terminal having an imaging function.

In each of the above embodiments, various processors shown below can be used as the hardware structure of the control unit using the processor 25 as an example. The above various processors include not only a CPU which is a general-purpose processor that functions by executing software (programs) but also a processor that has a changeable circuit configuration after manufacturing, such as an FPGA. The FPGA includes a dedicated electrical circuit that is a processor which has a dedicated circuit configuration designed to execute specific processing, such as PLD or ASIC, and the like.

The control unit may be configured by one of these various processors or a combination of two or more of the processors of the same type or different types (for example, a combination of a plurality of FPGAs or a combination of a CPU and an FPGA). Alternatively, a plurality of control units may be configured with one processor.

A plurality of examples in which a plurality of control units are configured as one processor can be considered. As a first example, there is an aspect in which one or more CPUs and software are combined to configure one processor and the processor functions as a plurality of control units, as represented by a computer such as a client and a server. As a second example, there is an aspect in which a processor that implements the functions of the entire system, which includes a plurality of control units, with one IC chip is used, as represented by system on chip (SOC). In this manner, the control unit can be configured by using one or more of the above various processors as the hardware structure.

Furthermore, more specifically, it is possible to use an electrical circuit in which circuit elements such as semiconductor elements are combined, as the hardware structure of these various processors.

Contents described and illustrated above are for detailed description of a portion according to the technique of the present disclosure and are only an example of the technique of the present disclosure. For example, the descriptions regarding the configurations, the functions, the actions, and the effects are descriptions regarding an example of the configurations, the functions, the actions, and the effects of the part according to the technique of the present disclosure. Accordingly, in the contents described and the contents shown hereinabove, it is needless to say that removal of an unnecessary part, or addition or replacement of a new element may be employed within a range not departing from the gist of the present technique of the present disclosure. Furthermore, to avoid confusion and to facilitate understanding of a part according to the technique of the present disclosure, description relating to common technical knowledge and the like that does not require particular description to enable implementation of the technique of the present disclosure is omitted from the content of the above description and from the content of the drawings.

In a case where all of documents, patent applications, and technical standard described in the specification are built into the specification as references, to the same degree as a case where the incorporation of each of documents, patent applications, and technical standard as references is specifically and individually noted.

The following technique can be understood from the above description.

### Supplementary Note 1

A creation method comprising:
an acquisition step of acquiring first sound data of a floating point format, based on a sound that is generated from a sound source and is collected by a sound collection device; and
an accessory information creation step of creating accessory information that is attached to the first sound data and includes device information, which relates to the sound collection device, or sound source information, which relates to the sound source.

### Supplementary Note 2

The creation method according to Supplementary Note 1,
wherein the first sound data is used to create second sound data having the number of bits, which is smaller than the number of bits of the first sound data.

### Supplementary Note 3

The creation method according to Supplementary Note 1 or 2,
wherein the accessory information includes the device information.

### Supplementary Note 4

The creation method according to Supplementary Note 3,
wherein the device information relates to gain processing used for the sound collected by the sound collection device or relates to performance of the sound collection device.

### Supplementary Note 5

The creation method according to Supplementary Note 2,
wherein the accessory information includes the sound source information.

### Supplementary Note 6

The creation method according to Supplementary Note 5,
wherein the sound source information is associated with time information included in the first sound data.

### Supplementary Note 7

The creation method according to Supplementary Note 5 or 6, further comprising:
an imaging step of creating, by an imaging apparatus, video data corresponding to the first sound data.

### Supplementary Note 8

The creation method according to Supplementary Note 7,
wherein the sound source is a subject included in the video data.

### Supplementary Note 9

The creation method according to Supplementary Note 7,
wherein the sound source is a main subject selected from a plurality of subjects included in the video data.

### Supplementary Note 10

The creation method according to Supplementary Note 7,
wherein the sound source information is a type of a drive sound accompanied by drive of the imaging apparatus.

### Supplementary Note 11

The creation method according to any one of Supplementary Notes 1 to 10, further comprising:
a first file creation step of creating a first file including the first sound data and the accessory information.

### Supplementary Note 12

The creation method according to Supplementary Note 11, further comprising:
an editing step of editing the first sound data based on the accessory information to create second sound data having the number of bits, which is smaller than the number of bits of the first sound data.

### Supplementary Note 13

The creation method according to Supplementary Note 12,
wherein, in the editing step, deterioration information that relates to a sound of the second sound data deteriorated by the editing is created, and a second file including the second sound data and the deterioration information is created.

### Supplementary Note 14

The creation method according to Supplementary Note 13,
wherein the second file includes the accessory information.

What is claimed is:

1. A creation method comprising:
an acquisition step of acquiring first sound data of a floating point format, based on a sound that is generated from a sound source and is collected by a sound collection device; and
an accessory information creation step of creating accessory information that is attached to the first sound data and includes device information, which relates to the sound collection device, or sound source information, which relates to the sound source.

2. The creation method according to claim 1,
wherein the first sound data is used to create second sound data having the number of bits, which is smaller than the number of bits of the first sound data.

3. The creation method according to claim 2,
wherein the accessory information includes the device information.

4. The creation method according to claim 3,
wherein the device information relates to gain processing used for the sound collected by the sound collection device or relates to performance of the sound collection device.

5. The creation method according to claim 2,
wherein the accessory information includes the sound source information.

6. The creation method according to claim 5,
wherein the sound source information is associated with time information included in the first sound data.

7. The creation method according to claim 5, further comprising:
an imaging step of creating, by an imaging apparatus, video data corresponding to the first sound data.

8. The creation method according to claim 7,
wherein the sound source is a subject included in the video data.

9. The creation method according to claim 7,
wherein the sound source is a main subject selected from a plurality of subjects included in the video data.

10. The creation method according to claim 7,
wherein the sound source information is a type of a drive sound accompanied by drive of the imaging apparatus.

11. The creation method according to claim 1, further comprising:
a first file creation step of creating a first file including the first sound data and the accessory information.

12. The creation method according to claim 11, further comprising:
an editing step of editing the first sound data based on the accessory information to create second sound data having the number of bits, which is smaller than the number of bits of the first sound data.

13. The creation method according to claim 12,
wherein, in the editing step, deterioration information that relates to a sound of the second sound data deteriorated by the editing is created, and a second file including the second sound data and the deterioration information is created.

14. The creation method according to claim 13,
wherein the second file includes the accessory information.

15. A creation apparatus comprising:
a processor, wherein the processor is configured to execute
an acquisition step of acquiring first sound data of a floating point format, based on a sound that is generated from a sound source and is collected by a sound collection device, and
an accessory information creation step of creating accessory information that is attached to the first sound data and includes device information, which relates to the sound collection device, or sound source information, which relates to the sound source.
